(19) United States
(12) Patent Application Publication
(10) Pub. No.: US 2015/0364466 A1
(43) Pub. Date: Dec. 17, 2015

(54) SELECTING CIRCUITS OF A MULTI-LEVEL INTEGRATED CIRCUIT

(71) Applicant: HEWLETT-PACKARD DEVELOPMENT COMPANY, L.P., Houston, TX (US)

(72) Inventors: Joseph A. Tucek, Palo Alto, CA (US); Eric A. Anderson, Palo Alto, CA (US)

(21) Appl. No.: 14/764,214

(22) PCT Filed: Jan. 31, 2013
(86) PCT No.: PCT/US2013/024097

§ 371 Date: Jul. 29, 2015

(51) Int. Cl. H01L 27/06; H01L 23/522

(52) U.S. Cl. CPC H01L 27/0688; H01L 23/522

(57) ABSTRACT

A multiple level integrated circuit includes a plurality of circuits, which are associated with different levels of the integrated circuit and are adapted to propagate a signal among the circuits. The signal has one of multiple states and the states include a first state that indicates circuit selection. The plurality of circuits are adapted to alter the signal as the signal propagates among the circuits to regulate which circuit of the plurality of circuits responds to the first state.

### BACKGROUND

Components (logic gates, transistors, memory cells and so forth) have traditionally been fabricated in an integrated circuit (IC) in a single level that includes multiple layers. In this manner, the level includes layers to form doped wells, inner wells, gate contacts, gate dielectric layers, logic traces, metal contacts, vias, trace wiring, and so forth for purposes of forming components of the level, which are distributed in the two dimensional (2-D) space of the level. For purposes of increasing component density, a more recently introduced IC manufacturing technology may be used to create a three-dimensional (3-D) IC, also referred to as a multi-level IC. As its name implies, the multi-level IC contains multiple levels in which the levels and components contained therein are “stacked” on each other.

### BRIEF DESCRIPTION OF THE DRAWINGS

FIG. 1 is an exploded schematic view of a multi-level integrated circuit (IC) according to an example implementation.

FIGS. 2, 3, 4 and 5 depict example layers of a level of a multi-level IC according to an example implementation.

FIGS. 6, 7, 8 and 9 depict example layers of a level of a multi-level IC according to a further implementation.

FIG. 10 depicts a layer of a level of a multi-level IC according to a further implementation.

FIG. 11 is a schematic diagram of a physical machine according to an example implementation.

FIG. 12 is a flowchart illustrating a technique of selecting a level in a multi-level circuit according to an example implementation.

### DETAILED DESCRIPTION

Systems and techniques are disclosed herein for fabricating and selectively activating circuits associated with different levels of a three-dimensional (3-D), or multi-level, integrated circuit (IC). This selection may be used, for example, in a multi-level memory device for purposes of selecting vertically stacked memory storage cells that are fabricated on different levels of the memory device. The techniques and systems that are disclosed herein may be used in many other applications, as can be appreciated by the skilled artisan in view of the description, drawings and claims.

It is noted that the multi-level IC may be fabricated using one of many different manufacturing technologies for fabricating such an IC. As examples, in some implementations, the multi-level IC may be fabricated on a monolithic substrate. In other implementations, such manufacturing processes as die-on-die, wafer-on die or wafer-on-wafer fabrication may be employed. Moreover, the multi-level IC may or may not include a semiconductor substrate, depending on the particular implementation. For example, in some implementations, the multi-level IC may be a memristor memory device that is formed from metal oxides in a non-semiconductor substrate, and which does not include a semiconductor substrate. In further implementations, as another example, the multi-level IC may be a memristor memory device that includes a semiconductor substrate that contains logic to aid in the level selection. Moreover, although example references are made herein to terms associated with photolithography (such as mask sets, for example), other microlithographic techniques (nano-imprint lithography or interference lithography and the associated mold sets, as examples) may be used, in accordance with further example implementations. Thus, many variations are contemplated, which are within the scope of the appended claims.

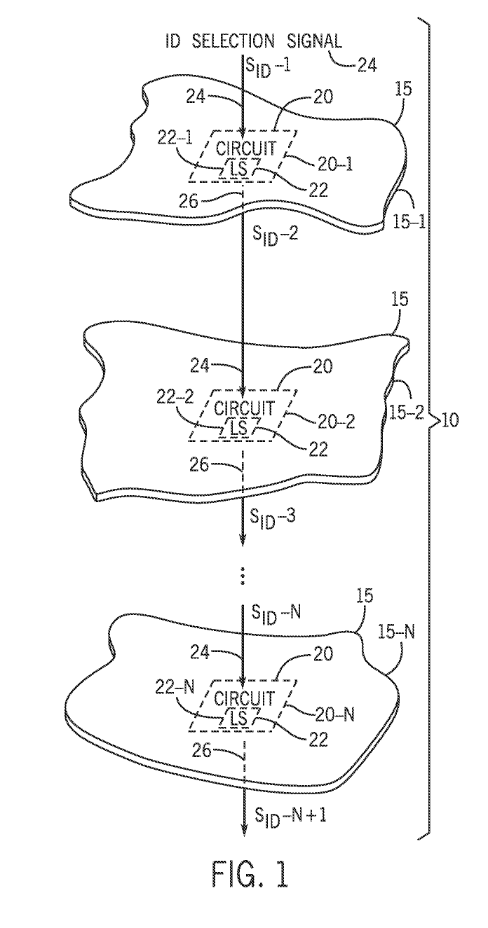

Referring to FIG. 1, in accordance with an example implementation, a multi-level IC 10 includes multiple levels 15 (levels 15-1, 15-2 . . . 15-N, being depicted in FIG. 1) that are vertically stacked, or oriented, with respect to each other. In general, each level 15 contains one or more layers, such as one or more metal layers, oxide layers, doped layers, and so forth, for purposes of forming doped wells, inner wells, gate contacts, gate dielectric layers, logic traces, metal contacts, vias, trace wiring, and so forth for components of the level 15, which are arranged in a two dimensional (2-D) space. Thus, in general, a given level 15 is a complete set of the layers to define a particular 2-D arrangement of components (counters, memory cells, multiplexers, decoders, and so forth).

For example implementations that are disclosed herein, each level 15 has an associated exemplary circuit 20 (circuits 20-1, 20-2 . . . 20-N being depicted in FIG. 1 and being associated with the levels 15-1, 15-2 . . . 15-N, respectively) that is constructed to be selectively activated. In accordance with an example implementation, the circuits 20 may be memory cells (memristor cells, for example) that are associated with different rows or columns of a memory storage array, and as an example, one of the circuits 20 is selected and therefore, activated at any one time. In further implementations, multiple circuits 20 may be selected/activated at any one time.

For purposes of the circuit selection, each circuit 20 contains a level select circuit 22 (level select circuits 22-1, 22-2 . . . 22-N being depicted in FIG. 1 and being part of the circuits 20-1, 20-2 . . . 20-N, respectively). In this regards, as further disclosed herein, a level selection signal (called “S_{ID}” herein) serially propagates among the level select circuits for this purpose.

In accordance with exemplary systems and techniques that are disclosed herein, the level select circuits 22 are identical in design, and in accordance with some implementations the circuits 20 may be identical in design (for example, the level select circuits 22 and associated memory cells may be identical in design). Due to the use of identical circuits for the different levels 15, the number of masks that may otherwise be used to fabricate the multi-level IC 10 is significantly reduced, thereby decreasing costs involved in fabricating the IC 10. In other words, in accordance with example implementations, the level select circuits 22 and/or the circuits 20 may be fabricated using the same mask set.

Although the level select circuits 22 may be identical, techniques and systems are disclosed herein for purposes of selectively activating the level select circuits 22 using a single S_{ID} level selection signal that is provided to the level select circuit 22 at the top or bottom of the stack (depending on the implementation) and serially propagates through the remaining level select circuits 22. Being identical, the level select circuits 22 are each constructed to be activated when the received S_{ID} level selection signal indicates, or represents, the same given predetermined value. In this regard, as disclosed herein, as the S_{ID} level selection signal propagates through the level select circuits 22, each circuit 22 alters the value indicated by the signal, thereby allowing the signal to, for one of the circuits 22, indicate a value that triggers the selection/activation of the circuit 22.

More specifically, in accordance with an example implementation, the uppermost level select circuit 22-1 receives an S_{ID}-1 level selection signal, where the “-1” suffix denotes the S_{ID} level selection signal representing a particular value (a certain “count,” for example). Here, the “-1” suffix denotes the S_{ID}-1 level selection signal as representing its initial value. As an example, the S_{ID}-1 level selection signal may be furnished by a row or column address decoder (for implementations in which the multi-level IC 10 is a memory device, for example). The uppermost level select circuit 22-1 alters the S_{ID}-1 level selection signal (in the same manner that the other level select circuits 22 alter the received S_{ID} level selection signal) before furnishing the altered signal (now called the “S_{ID}-2” level selection signal) to the next level select circuit 22-2 in the serial chain of level select circuits 22.

As a more specific example, in accordance with some implementations, each level select circuit 22 is constructed to perform a mathematic alteration of the received S_{ID} level section signal to add or subtract a certain value. For example, in some example implementations, each level select circuit 22 is constructed to increment, or add a “1,” to a count value that is indicated by the received S_{ID} level selection signal. In further implementations, each level select circuit 22 is constructed to decrement, or subtract “1” from the received S_{ID} selection signal. For example, the level selection signal S_{ID}-1 may indicate an initial count value of “0.” The uppermost level select circuit 22-1 increments the count value so that the S_{ID}-1 level selection signal indicates a count value of “1.” Likewise, the level select circuit 22-2 increments the count value so that the S_{ID}-3 level selection signal indicates a count value of “2.” Thus, in general, an S_{ID}-N level selection signal that is received by a given level select circuit 22-N has a count value that is one less than the count value of the S_{ID}-N+1 level selection signal that is provided by the level select circuit 22-N to the next level select circuit 22-N+1. Therefore, although the level select circuits 22 are identical and are constructed to be selected/activated by the same value, because each level select circuit 22 receives a different value, the initial value indicated by the S_{ID}-1 level selection signal may be adjusted as appropriate to select/activate a given circuit 22.

As an example, the level select circuit 22, in general, may be constructed to be activated in response to receiving an S_{ID} selection signal that indicates a value of “5.” To select the uppermost level select circuit 22-1, an S_{ID}-1 selection signal indicating a value of “5” may therefore be furnished to the circuit 22-1. The level select circuit 22-1, as well as the other level select circuits 22 alter this value so that none of the other circuits 22 receive an S_{ID} selection signal that indicates a value of “5.” Continuing the example, if the third level select circuit 22-3 (not shown in FIG. 1) is to be selected, then an S_{ID}-1 selection signal indicating a value of “3” is furnished to the level select circuit 22-1, which results in a count value of 5 for the S_{ID} selection signal that is received by the level select circuit 22-3 (due to the level select circuits 22-1 and 22-2 each incrementing the value by “one”).

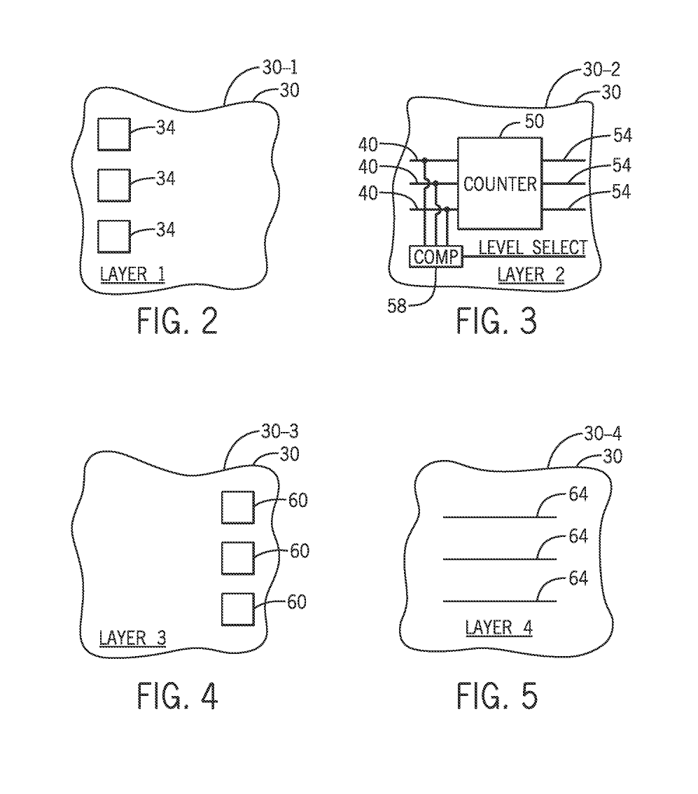

In accordance with an example implementation, the level select circuit 22 may be formed from four layers 30 that are depicted in FIG. 2 (lowermost layer 30-1), FIG. 3 (second layer 30-2 from bottom), FIG. 4 (third layer 30-3 from bottom) and FIG. 5 (uppermost layer 30-4). It is noted that the vertical ordering of the layers depicted in FIGS. 2, 3, 4 and 5 may be reversed in accordance with further exemplary implementations.

The first, or lowermost, layer 30-1 (FIG. 2) of the level select circuit 22 contains a metal layer to form vias 34 for purposes of routing the S_{ID} selection signal (a three bit digital signal, for this example) that has been altered by the level circuit 22 to the adjacent level select circuit 22 below. The second layer 30-2 contains layers to form a counter 50, or logic, which furnishes three bits of the S_{ID} selection signal to metal traces 40 that are coupled to the vias 34 (see FIG. 2) of the lowermost layer 30-1. For this example, a comparator 58 of the layer 30-2 compares the three bit counter output to a predetermined count value to identify a match. When a match occurs, the comparator 58 asserts (drives to logic one, for example) a signal called “LEVEL SELECT” for purposes of selecting the level selection circuit 22 and, for example, selecting the remaining circuit 20 (see FIG. 1). In further implementations, the comparator 58 may be alternatively coupled to compare the three bits that are present on three input terminals 54 of the counter 50. Thus, many variations are contemplated, which are within the scope of the appended claims.

The three input terminals 54 of the counter 50 are coupled by vias 60 of the third layer 30-3 (see FIG. 4) to wire traces 64 of the uppermost, or fourth layer 30-4 (see FIG. 5). Thus, the wire traces 64 receive the S_{ID} selection signal from the level select circuit 22 above or from the source of the initial S_{ID}-1 selection signal, whichever is applicable.

Less dense coding may be employed, in accordance with further implementations, for purposes of minimizing the complexity of the level select circuit 22. In this manner, in further implementations, a one hot counter may be employed, in which the level select circuit 22 does not contain any logic devices. In the one hot counter design, one bit of the three bit value (assuming a three bit value for this example) is a logic one, with the remaining two bits being logic zeros. The logic one bit (i.e., the “hot bit”) is shifted, or rotated, in bit position by each level select circuit 22 so that values as they propagate through the circuits 22 to form a sequence of a repeating pattern of three: 100, 010, 001, 100, 010, 001, 100, 010, and so forth. Such a design may be particularly advantageous for certain devices (memristor devices, for example) that may not otherwise logic or employ use a semiconductor substrate.

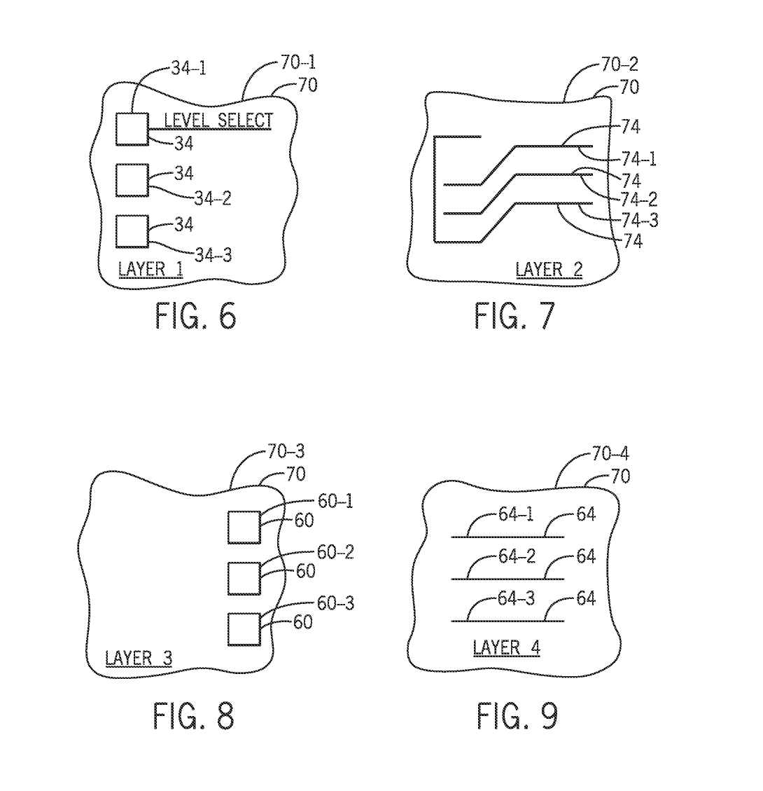

As a more specific example, FIGS. 6, 7, 8 and 9 depict corresponding first 70-1, second 70-2, third 70-3 and fourth 70-4 layers, respectively, of the level select circuit in accordance with further implementations in which a one hot counter is employed. Similar to the first layer 30-1, the first layer 70-1 (see FIG. 6) has three vias 34 (specific vias 34-1, 34-2 and 34-3 being depicted in FIG. 6) for purposes of furnishing a three bit S_{ID} level selection signal to the adjacent level select circuit 22 below. One of the vias 34, such as the via 34-1, is designated to provide the LEVEL SELECT signal.

The second layer 70-2 (FIG. 7) includes metal traces 74 (traces 74-1, 74-2 and 74-3, being depicted in FIG. 7), which route signals between the vias 34 (FIG. 6) of the first layer 70-1 and vias 60 of the third layer 70-3 (FIG. 8). The routing is designed to perform a logical shifting of the bits of the S_{ID} level selection signal value in a manner that increments the value by one. For example, in accordance with some implementations, the bit shifting is performed by the traces 74 coupling the vias 60-1, 60-2 and 60-3 to the vias 34-2, 34-3 and 34-1, respectively. Thus, metal trace 74-1 couples the vias 60-1 and 34-2 together; metal trace 74-2 couples the vias 60-2 and 34-2 together; and metal trace 74-3 couples the vias 60-3 and 34-1 together.

Using the one hot counter, level selection may be performed as follows. For this example, the shift is a right shift (a right rotate such that a right shift of the bits “001” produces the bits “100”); at each level, the right shift is performed before the comparison is made to detect selection of the level; and the level select indication is tied to the rightmost bit, so that the level that has the bits “001” after it right shifts is considered selected. As an example, the uppermost level select circuit 22 may receive S_{ID}-1 level selection signal (see FIG. 1), which, for example, has a three bit value of “001.” The bit shifting performed by the level select circuits 22 shifts the bits of the S_{ID} level selection signal to provide the values “100,” “010,” and “001,” from the first 22-1, second 22-2 and third 22-3 level select circuits, respectively. As an example, communicating a S_{ID}-1 level selection signal representing a “010” causes the LEVEL_SELECT signal at the via 34-1 of the level select circuit 22-1 to be asserted to select the level select circuit 22-1. As another example, communicating a S_{ID}-1 level selection signal representing a “100” results in selection of the level select circuit 22-2; and as yet another example, communicating a S_{ID}-1 level selection signal representing a “001” results in selection of the level select circuit 22-3 (not shown).

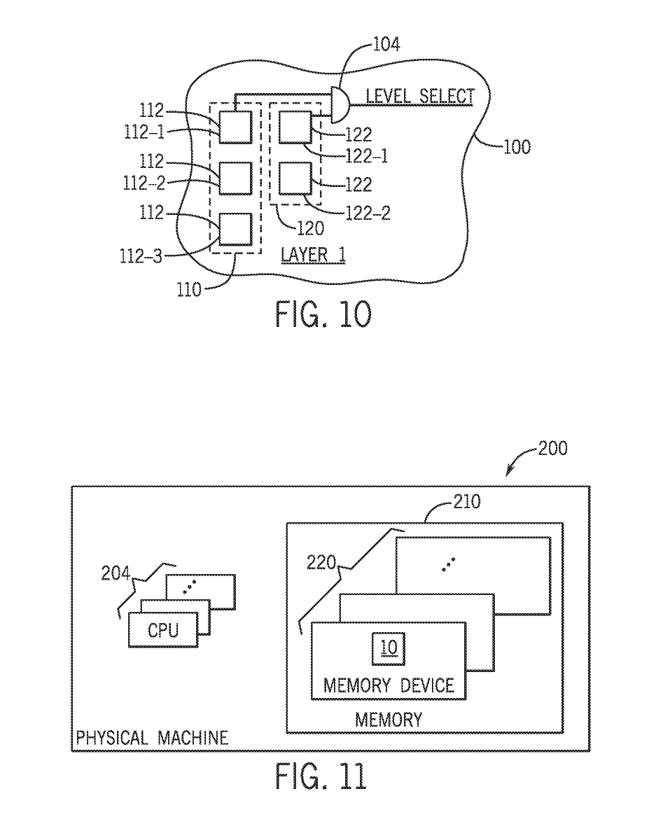

Referring to FIG. 10, in a further implementation, a topology that uses multiple one hot counters may be employed for purposes of increasing the number of level select circuits 22 that may be selected. For example, FIG. 10 depicts a first layer 100 of such a level select circuit, in accordance with further implementations. The first layer 100 includes two sets of vias 110 and 120. In this regard, the first set 110 includes three vias 112-1, 112-2 and 112-3, which, are coupled to bit shifting, metal trace routing (as discussed above) to form a three bit, one hot counter. The second set of vias 120 has two vias 122-1 and 122-2, which use bit shifting, metal trace routing to form a two bit, one hot counter. An AND gate 104 of the layer 100 is coupled to the vias 112-1 and 122-1, as depicted in FIG. 10 for purposes of generating the LEVEL SELECT signal.

Thus, for this example, five vias may address six levels. By selecting the size of the two one hot counters to be relatively prime numbers j and k, j*k levels may be selected using the j+k vias. In accordance with some example implementations, the j and k number of vias may be set to be nearly as equal as possible, which allows for relatively more efficient selection than, for example, a single one hot encoded signal. For example, for j=6 and k=5, these eleven vias may select thirty levels. Similarly, in further example implementations, three or four sets of one hot signals, all relatively prime, may be used with a larger capacity AND gate. Thus, a set of three wide, four wide and five wide one hot signals may be used, for example, for purposes of addressing sixty levels using twelve vias and a three input AND gate. Once again, the closer the number of vias of the different sets, the larger the range. For example, a two wide, three wide and five wide arrangement of vias permits the selection of thirty levels with ten vias using a three input AND gate.

Other implementations are contemplated and are within the scope of the appended claims. For example, in accordance with further example implementations, non-relatively prime counter sizes (j=7 and k=4 to allocate eleven vias to select twenty eight levels, as an example) may be selected. As another example, in accordance with further implementations, inverse signaling, such as the use of a one cold counter (i.e., the bit indicative of logic zero is the “cold” bit with the other bits being logic ones) may allow a reduction in logic size by allowing the use of a NOR gate to provide the LEVEL SELECT signal instead of using the above-described AND gate. Other variations are contemplated, which are within the scope of the appended claims.

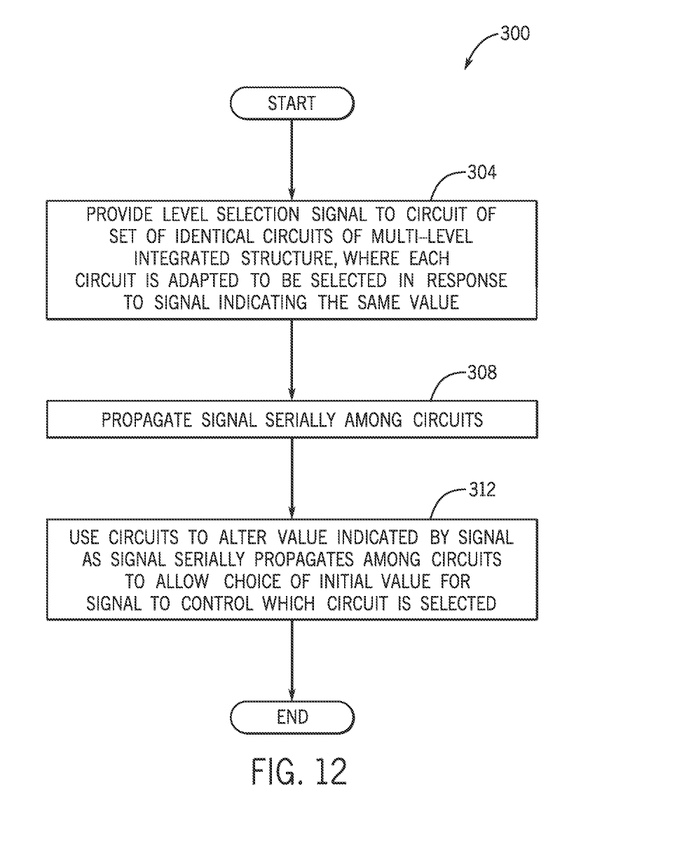

Thus, referring to FIG. 12, in accordance with example implementations, a technique 300 includes providing (block 304) a level selection signal to a circuit of a set of identical circuits of a multi-level integrated structure, where each of the circuits is adapted to be selected in response to a signal that is indicative of the same value. The signal is serially propagated among the circuits, pursuant to block 308. The circuits are used to alter a value indicated by the signal as the signal serially propagates among the circuits to allow choice of the initial value for the signal to control which circuit is selected by the signal, pursuant to block 312.

The circuits 20 may be used in a multi-level integrated circuit in numerous different applications, depending on the particular implementation. For example, referring to FIG. 11, in accordance with some implementations, the multi-level integrated circuit 10 may be used to form a memory device 220 (a memristor, for example). In this regard, a physical machine 200 may include many such memory devices 220 to form a memory 210 of the physical machine 200. The physical machine 200 may, in general, be an actual machine made up of actual hardware and software. For example, the hardware includes such devices as the memory devices 220 and one or more central processing units (CPUs) 204. The physical machine 200 may include various other hardware devices, such as input/output (I/O) devices, network interfaces, displays, and so forth. Moreover, the physical machine 200 may contain software in the form of machine executable instructions that are executed by the CPU(s) 204 for purposes of forming applications, device drivers, operating systems, and so forth. As examples, the physical machine 200 may be a server, a client, a laptop computer, an ultrabook computer, a tablet computer, a smartphone, and so forth, depending on the particular implementation.

Among the advantages of the level selection techniques and apparatuses disclosed herein, multiple mask sets or electronic beam editing per level of circuitry may not be used. Moreover, the logic supportive on each level may be fairly low performance and/or low area. Moreover, as disclosed herein, the level selection may not contain any logic. Additionally, in the case of a memory device, the level selection potentially reduces the number of vias, as compared to providing the signals to individually address each level separately. Other and different advantages are contemplated, in accordance with the scope of the appended claims.

While a limited number of examples have been disclosed herein, those skilled in the art, having the benefit of this disclosure, will appreciate numerous modifications and variations therefrom. It is intended that the appended claims cover all such modifications and variations.

What is claimed is:

1. An apparatus comprising:
a multiple level integrated circuit comprising a plurality of circuits associated with different levels of the integrated circuit;
wherein:
the plurality of circuits are adapted to propagate a signal among the circuits, the signal having one of multiple states and the states comprising a first state indicating circuit selection; and
the plurality of circuits are adapted to alter the signal as the signal propagates among the circuits to regulate which circuit of the plurality of circuits responds to the first state.

2. The apparatus of claim 1, wherein the plurality of circuits comprises identical circuits.

3. The apparatus of claim 1, wherein the plurality of circuits are fabricated using the same set of masks.

4. The apparatus of claim 1, wherein the states comprise digital values, and at least one circuit of the plurality of circuits is adapted to receive the signal and alter the signal to change a digital value indicated by the received signal to another digital value.

5. The apparatus of claim 4, wherein the at least one circuit comprises a counter to alter the signal to change the digital value.

6. The apparatus of claim 4, wherein the at least one circuit comprises a metal layer comprising traces arranged to alter the signal to change the digital value.

7. The apparatus of claim 6, wherein the traces are arranged to shift bits of the digital value of the received signal.

8. The apparatus of claim 1, wherein the plurality of circuits are adapted to propagate another signal among the circuits, the another signal having one of multiple states and the states of the another signal comprising a second state such that a combination of the first and second states indicates circuit selection; and
the plurality of circuits are adapted to alter the another signal as the another signal propagates among the circuits to regulate which circuit of the plurality of circuits is selected.

9. The apparatus of claim 8, wherein at least one of the circuits of the plurality of circuits comprises logic to generate a selection signal for the circuit in response to detection of the first and second states.

10. An apparatus comprising:
a multiple level integrated circuit comprising a plurality of identical circuits associated with different levels of the integrated circuit:
wherein:
the plurality of circuits are adapted to propagate a signal indicative of a count value among the circuits, the count value being equal to a given value to indicate circuit selection; and
the plurality of circuits are adapted to change the count value indicated by the signal as the signal propagates among the circuits to regulate which circuit of the plurality of circuits responds to the count value indicated by the signal being equal to the given count value.

11. The apparatus of claim 10, wherein at least one circuit of the plurality of circuits comprises logic to change the count value or wire traces coupled to vias to shift bits of the count value to change the count value.

12. A method comprising:
providing a signal to a circuit to a plurality of circuits of a multiple level integrated circuit to cause the signal to propagate among the plurality of circuits, the plurality of circuits being associated with different levels of the integrated circuit, the signal having one of multiple states and the states comprising a first state indicating circuit selection; and
using the signal to select a circuit of the plurality of circuits, wherein using comprises using the signals to alter the signal as the signal propagates among the circuits to regulate which circuit of the plurality of circuits responds to the first state.

13. The method of claim 12, wherein the states comprise count values, and using the signal to select the circuit comprises:
using at least one circuit of the plurality of circuits to receive the signal and alter the signal to change a digital value indicated by the received signal to another digital value.

14. The method of claim 12, wherein using the at least one circuit to alter the signal comprises using logic of the at least one circuit to change the digital value.

15. The method of claim 12, wherein using the at least one circuit to alter the signal comprises using a routing of metal traces among vias to shift bits of the digital value to change the digital value.
